(19) United States
(12) Patent Application Publication
(10) Pub. No.: US 2004/0162121 A1
(43) Pub. Date: Aug. 19, 2004

(54) Personal communication systems

(76) Inventors: Claire Elizabeth Bamber, Cincinnati, OH (US); Jeffrey Vincent Bamber, Cincinnati, OH (US)

Correspondence Address: JEFFREY V. BAMBER, 5023 VILLAGE DRIVE, CINCINNATI, OH, 45244, US

(21) Appl. No.: 10/780,312

(22) Filed: Feb. 17, 2004

Related U.S. Application Data
(63) Continuation-in-part of application No. 10/368,905, filed on Feb. 18, 2003.
(60) Provisional application No. 60/358,039, filed on Feb. 19, 2002.

(51) Int. Cl. H04B 1/06; H05K 11/00

(52) U.S. Cl. 455/575.6; 455/344

(57) ABSTRACT

Personal communication systems, and more particularly, in some embodiments, personal communication systems that can be worn are disclosed. In other embodiments, the features of the personal communication systems described herein may be applied to types of personal communication devices that are carried, rather than worn. In one non-limiting embodiment, the personal communication system comprises a device having a microphone that is located on the user's hand, such as on one of the user's fingers and an ear piece that is located on another portion of the user's hand, such as on another one of the wearer's fingers.

### CROSS-REFERENCE TO RELATED APPLICATIONS

This application claims the benefit of the filing date of U.S. Provisional patent application Serial No. 60/358,039, filed on Feb. 19, 2002, and is a continuation-in-part of U.S. patent application Ser. No. 10/368,905, filed on Feb. 18, 2003, both of which are incorporated by reference herein.

### FIELD OF THE INVENTION

The present invention relates to personal communication systems, and more particularly, in some embodiments, to personal communication systems that can be worn. In other embodiments, the features of the personal communication systems described herein may be applied to types of personal communication devices that are carried, rather than worn.

### BACKGROUND OF THE INVENTION

There is an increasing need for personal communication systems, such as cellular phones, and the like, that can be more conveniently be carried and used. Oftentimes, cellular phones cannot be conveniently carried by a person in their pockets, purses or the like. This may be due to the size of the phone, or the difficulty of removing the cellular phone from their pocket, purses or the like. This is especially true when a person is driving in a vehicle and has their seat belt fastened. Similar difficulties arise when the person attempts to hold their cellular phone when driving a car or other vehicle.

U.S. Pat. No. 6,212,414 B1 issued to Alameh, et al., assigned to Motorola, Inc., is directed to a wrist-carried radiotelephone. The wrist-carried radiotelephone described in this patent has a microphone located in the wristband or housing of the radiotelephone, or in a headset. The ear piece of the radiotelephone can be at the end of a retractable tether. The ear piece can be configured to fit at the base between two of the user's fingers near the user's palm. Alternatively, the ear piece can be a ring to be worn on the user's finger and held in proximity to the user's ear. In the embodiments disclosed in this patent, the microphone and the ear piece are not as conveniently located as they could be so that the microphone is located near the user's mouth and the ear piece is located near the user's ear.

Thus, there is a need to provide personal communication systems, such as cellular phones, and the like, that can be more conveniently be carried and used.

### SUMMARY OF THE INVENTION

The present invention relates to personal communication systems, and more particularly, in some embodiments, to personal communication systems that can be worn. In other embodiments, the features of the personal communication systems described herein may be applied to types of personal communication devices that are carried, rather than worn.

There are numerous, non-limiting embodiments of the invention. All embodiments, even if they are only described as being “embodiments” of the invention, are intended to be non-limiting (that is, there may be other embodiments in addition to these), unless they are expressly described as limiting the scope of the invention.

In one non-limiting embodiment, the personal communication system comprises a device such as a cellular telephone having a microphone that is located on the user's hand, such as on one of the user's fingers and an ear piece that is either located on another portion of the user's hand, such as on another one of the wearer's fingers (including the user's thumbs), or is located within or adjacent to the user's ear.

The main components of the personal communication system (such as the wrist unit, microphone, and ear piece) can be connected by wires, by wireless connections (e.g., wireless infared or radio frequency), or they can be independent units capable of operating together. If wires are used, the wires can, if desired, be retractable. If retractable wires are used, they can retract into the wrist unit, into the microphone, into the ear piece, or both. If retractable wires are used, they can either be detached (for example, unplugged) from the microphone and ear piece, or they can remain attached to at least one of these components. If the retractable wires retract into the wrist unit, and remain attached to the same, the wrist unit can have a configuration (for example, a recess) or component (for example a clip, etc.) that serves as a holder for the microphone and/or the ear piece. In addition, or alternatively, the wires can be decoratively configured (such as in the form of gold or silver chains, etc.).

In other embodiments, the ear pieces and/or microphones may be located on structures that are capable of extension or projection and/or retraction from another portion of the communication device, such as from the body of a telephone.

### BRIEF DESCRIPTION OF THE DRAWINGS

While the specification concludes with claims particularly pointing out and distinctly claiming the invention, it is believed that the present invention will be better understood from the following description taken in conjunction with the accompanying drawings in which:

FIG. 1 is a perspective view of one non-limiting embodiment of a personal communication system showing one way in which a user of the personal communication system might hold their hand when using the personal communication system.

FIG. 2 is a perspective view of the personal communication system shown in FIG. 1, shown with the wires retracting into the body of the wrist unit.

FIG. 3 is a partially fragmented perspective view of an embodiment of a personal communication system with a wrist unit that has a recess and a clip that serve as holders for the microphone and the ear piece.

FIG. 4 is a schematic front view of an alternative embodiment of a personal communication system in which the receiver and microphone are located on structures that at least partially reside inside the body of the personal communication system when the personal communication system is not in use.

FIG. 5 is a schematic cross-sectional view of the personal communication system shown in FIG. 4 taken along line 5-5 of FIG. 4.

FIG. 6 is a perspective view of the personal communication system similar to that shown in FIG. 1, only with the receiver and microphone being located on antennae-like structures that extend outward from the body of the device.

### DETAILED DESCRIPTION OF THE INVENTION

The present invention relates to personal communication systems, and more particularly, in some embodiments, to personal communications systems that can be worn. The term “personal communication systems”, as used herein, is intended to refer to communication systems for use by individuals and includes those used for personal and business purposes.

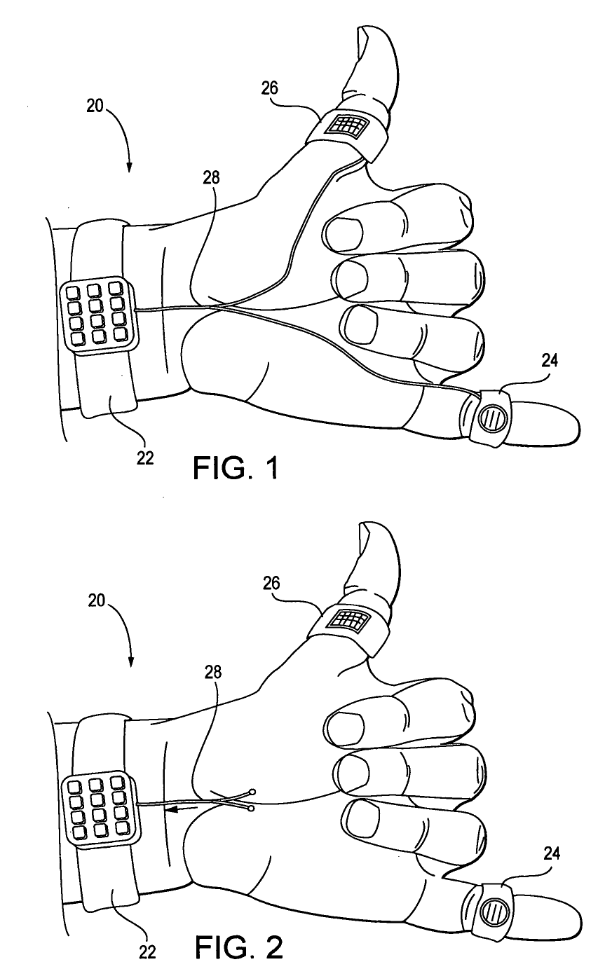

One non-limiting embodiment of the personal communication system is shown in FIG. 1. The personal communication system 20 shown in FIG. 1 can be a pager, a cellular telephone, a cordless telephone, or a personal communication service (PCS) radiotelephone, or any other type of device by which the user may communicate to another person or device (such devices include, but are not limited to computers).

In the embodiment shown in FIG. 1, the personal communication system 20 comprises a device such as a cellular telephone that has components located in a wrist unit 22 and a microphone 24 that is located on one of the user's fingers and a receiver or ear piece 26 that is located on another one of the wearer's fingers (including the user's thumbs).

The wrist unit 22 may, if desired, be in the configuration of a bracelet, wristwatch, or some other configuration. The wrist unit 22 may comprise a housing that contains some or all of the telephone circuitry. The housing can be located on any portion of the wrist unit 22. The housing can be located on a band, and can be located on the portion of the wearer's wrist that corresponds to the back of the user's hand, in the same manner that most watches are worn. In other embodiments, it can be located on the inside portion of the wearer's wrist as shown in FIG. 1, or on any other suitable location. In addition, instead of all the telephone circuitry residing in a housing, some or all of the telephone circuitry may reside in all or a portion of the band on the user's wrist.

The microphone 24 can be located on one of the wearer's fingers, such as on a ring worn on the user's fingers. In the non-limiting embodiment shown, the microphone 24 is worn on the user's pinkie finger. The ear piece 26 can be located on one of the wearer's other fingers, such as in the form of a ring worn on the wearer's thumb.

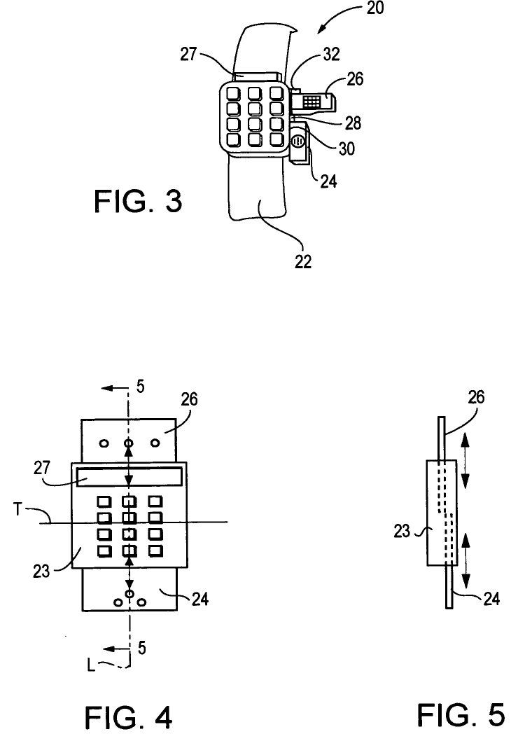

The personal communication system can be any type of device described in U.S. Pat. No. 6,212,414 B1 issued to Alameh, et al., and can have any of the components and features of the devices described therein. For example, the personal communication system may have a keypad, or it can use voice recognition software instead of, or in addition to a keypad. The personal communication system may also have a display 27 (shown in FIG. 3) for displaying any information desired, including, but not limited to names or the telephone numbers dialed for outgoing calls, or the telephone number or names associated with incoming calls.

The main components of the personal communication system 20 (such as the wrist unit 22, microphone 24, and ear piece 26) can be connected by wires 28, by wireless connections (e.g., wireless infared or radio frequency), or they can be independent units capable of operating together. In addition, or alternatively, the wires can be decoratively configured (such as in the form of gold or silver chains, etc.). If wires are used, the wires 28 can, if desired, be retractable. Suitable retractable wire technology that can be adapted for this purpose is available from ZIP-LINQ of Concord, Calif., USA. If retractable wires are used, as shown in FIG. 2, they can retract into the wrist unit 22. Alternatively, the retractable wires can retract into the microphone 24, into the ear piece 26, into both the microphone 24, and the ear piece 26, or into any combination of the wrist unit 22, the microphone 24, and the ear piece 26. If retractable wires are used, they can either be detached (for example, unplugged) from the microphone 24 and ear piece 26, or they can remain attached to at least one of these components. As shown in FIG. 3, if the retractable wires are configured to retract into the wrist unit 22 and remain attached to the microphone 24 and/or the ear piece 26, the wrist unit 22 can have a configuration (for example, a recess 30) or component (for example a clip 32, etc.) that serves as a holder for the microphone 24 and/or the ear piece 26.

It should be understood that the features described herein are not limited to use on personal communication systems that are worn on a band about the wearer's wrist. In other embodiments, personal communication systems having any of the features described herein can be of a type that is worn on some other portion of a person's body and/or clothing, or they may be of a type that is hand-held (such as in a user's palm) during use.

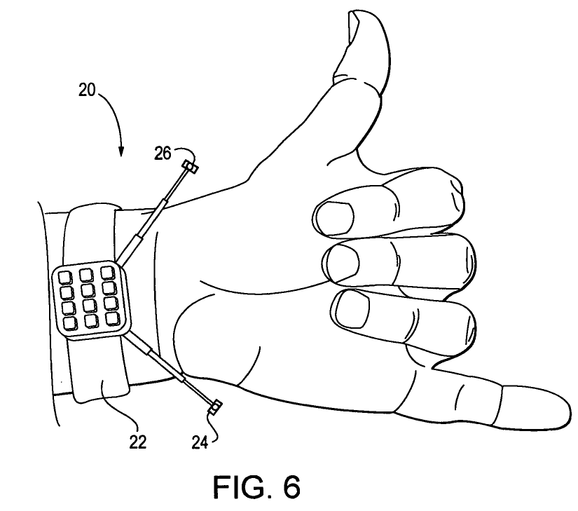

FIGS. 4 and 5 show that in other embodiments, the ear piece (or receiver) 26 and/or microphone 24 can be located on or within structures that can at least partially (or completely) reside inside the body of the personal communication system 20 when the personal communication system 20 is not in use. The microphone 24 and/or receiver 26 can be deployed when the personal communication system 20 is ready for use. The microphone 24 and/or receiver 26 can be provided on any suitable structure, and these structures can have any suitable configuration. The microphone 24 and/or receiver 26 can be connected to the body of the communication system through wires running inside or outside of these structures, or they can be connected thereto by wireless connections.

FIGS. 4 and 5 show structures in the form of flat panels that slide in and out of recesses in the body portion 23 of the communication device 20. As shown in FIG. 5, the recesses for these structures may be offset relative to each other. That is, the recesses need not lie along the same line. In other embodiments, the recesses may lie on the same line. These structures can extend outward at any suitable orientation from the body portion 23 of the communication device 20. As shown in FIG. 4, the structures on or in which the microphone 24 and/or receiver 26 are located can extend outward parallel to the longitudinal centerline L of the body portion 23 of the communication device 20 (such as in the direction of the arrows shown in FIG. 4). In other embodiments, one or both of the structures can extend outward in directions that are parallel to the transverse centerline T of the body 23 of the communication device 20. In other embodiments, one or both of the structures can extend outward in a direction that makes an angle with the longitudinal and transverse centerlines L and T.

FIG. 6 shows that in another embodiment, the microphone 24 and/or receiver 26 can be provided on a structure that is similar to the retractable, telescoping antennae that is used on cellular telephones. While FIG. 6 shows a communication device 20 that is worn on a wrist band, this embodiment is equally applicable to hand-held devices. The microphone 24 and/or ear piece 26 can be provided on any suitable portion of such a antennae structure, such as the end portion thereof. FIG. 6 shows that the structures on which the microphone 24 and/or ear piece 26 are located can extend outward at any suitable angle to the longitudinal centerline of the body portion of the communication device as shown in FIG. 6, and from any side of the body portion of the communication device, or (in other embodiments) from the wrist band (if this communication device is of a type worn on a wrist band), and at any suitable angle relative to the plane of the face of the body portion 23 of the communication device. The structures on which the microphone 24 and/or ear piece 26 are located can be located within any quadrant of a three dimensional coordinate system, and can form any suitable angle therebetween, including, but not limited to less than or equal to 180 degrees.

The structure(s) can be deployed in any suitable manner. In one version of such an embodiment, these portions of the communication device can be spring-loaded so that they can be released at a suitable time. For example, the structures can be released when the person desires to use the device, such as a cellular phone, and pushes a button to answer the phone and/or to make a call. In other words, the deployment of these structures can be integrated into another function of the communication device 20. In another version of this embodiment, these portions of the communication device can be deployed by a motor that causes them to extend from the body of the communication device. In another embodiment, these components of the device can be manually extendable, such as by a user pulling on a portion thereof.

The components of the personal communication system 20 can be assembled in any suitable manner, including the manner described in any of the patents incorporated by reference herein.

The personal communication system 20 can be used in a manner similar to a conventional cellular telephone, except that in the case of the embodiment shown in FIG. 1 of the drawings, the user will hold their hand adjacent to their head, with their thumb with the ear piece 26 thereon near their ear for listening, and their pinkie finger with the microphone 24 thereon near their mouth for speaking.

Numerous other arrangements are possible. In another embodiment, for example, the user can wear the microphone 24 on their thumb, possibly more toward the end of the same, and the ear piece 26 on their index finger, and can hold their thumb and index finger in an “L” configuration with their thumb by their mouth and the end of their index finger by their ear. In still other embodiments, the ear piece 26 can be in the form of an “ear bud” that the user places in their ear. Such an ear bud could be connected by wires to one or more of the other components, or it can be wireless.

The disclosure of all patents, patent applications (and any patents which issue thereon, as well as any corresponding published foreign patent applications), and publications mentioned throughout this description are hereby incorporated by reference herein. It is expressly not admitted, however, that any of the documents incorporated by reference herein teach or disclose the present invention.

It should be understood that every maximum numerical limitation given throughout this specification will include every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

While particular embodiments of the subject invention have been described, it will be obvious to those skilled in the art that various changes and modifications of the subject invention can be made without departing from the spirit and scope of the invention. In addition, while the present invention has been described in connection with certain specific embodiments thereof, it is to be understood that this is by way of illustration and not by way of limitation and the scope of the invention is defined solely by the appended claims which should be construed as broadly as the prior art will permit.

What is claimed is:

1. A personal communication system comprising the following components:
a wrist unit for wearing on a user's wrist;
a microphone that is located on a portion of the user's hand; and
an ear piece that is located on another portion of the user's hand, wherein said wrist unit, microphone, and ear piece are in a relationship where there is communication with at least one of the other components of the system during use of the system.

2. The personal communication system of claim 1 wherein the microphone is located on one of the user's fingers including the user's thumb, and the ear piece is located on another one of the user's fingers including the user's thumb.

3. The personal communication system of claim 2 wherein the microphone is located on the user's pinkie finger and the ear piece is located on the user's thumb.

4. The personal communication system of claim 2 wherein the microphone is located on the user's thumb and the ear piece is located on the user's index finger.

5. The personal communication system of claim 1 wherein at least some of said components are in communication via wires.

6. The personal communication system of claim 1 wherein at least some of said components are in wireless communication.

7. The personal communication system of claim 5 wherein at least some of the wires are retractable.

8. The personal communication system of claim 1 wherein said wrist unit comprises a holder for at least one of said microphone and ear piece.

9. The personal communication system of claim 8 wherein said holder is selected from the group consisting of a recess or a clip.

10. A personal communication system comprising:
a body portion, and at least one of the following components:
a microphone that is located on or within a first structure wherein at least a portion of said first structure at least partially resides inside the body of the personal communication system when the first structure is not deployed; and
a receiver that is located on or within a second structure wherein at least a portion of said second structure at least partially resides inside the body of the personal communication system when the second structure is not deployed,
wherein said body portion, microphone, and receiver are in a relationship where there is communication with at least one of the other components of the system during use of the system.

11. The personal communication system of claim 10 wherein: (a) said microphone is located on or within a structure wherein at least a portion of said structure at least partially resides inside the body of the personal communication system when the personal communication system is not in use, and (b) said receiver comprises an ear bud.

12. The personal communication system of claim 10 wherein at least a portion of at least one of said structures fits into a recess in the body of communication system.

13. The personal communication system of claim 10 wherein at least one of said structures is a telescoping member.

14. The personal communication system of claim 10 wherein at least one of said first and second structures is spring-loaded.

15. The personal communication system of claim 14 wherein said spring-loaded structure is configured so that it is deployed when another function of the communication device activated.
